(19) United States
(12) Patent Application Publication
(10) Pub. No.: US 2008/0227027 A1
(43) Pub. Date: Sep. 18, 2008

(54) Method for forming photoresist pattern and photoresist laminate

(76) Inventors: Akiyoshi Yamazaki, Kanagawa-ken (JP); Naoto Motoike, Kanagawa-ken (JP); Daisuke Kawana, Kanagawa-ken (JP); Kazufumi Sato, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 12/081,463

(22) Filed: Apr. 16, 2008

Related U.S. Application Data
(63) Continuation of application No. 11/703,790, filed on Feb. 8, 2007, now abandoned.
Application No. 11/703,790 is a continuation of application No. 11/196,742, filed on Aug. 4, 2005, now abandoned.
Application No. 11/196,742 is a continuation of application No. 10/857,953, filed on Jun. 2, 2004, now abandoned.
Application No. 10/857,953 is a continuation of application No. 10/307,988, filed on Dec. 3, 2002, now abandoned.

(30) Foreign Application Priority Data
Dec. 3, 2001 (JP) 2001-369353

(51) Int. Cl. G03F 7/004; G03F 7/20

(52) U.S. Cl. 430/270.1; 430/322

(57) ABSTRACT

A method for forming a photoresist pattern involves the steps of: depositing a photoresist film on a substrate, the photoresist film containing an acid-generating agent capable of generating an acid upon exposure to light; overlaying an antireflective film over the photoresist film, the antireflective film containing a fluorine-based acidic compound; selectively exposing the photoresist; and developing the photoresist. The novel method is characterized in that the acid-generating agent and the fluorine-based acidic compound are selected so that the acid that the acid-generating agent generates in the photoresist film upon exposure to light has a higher acidity than the fluorine-based acidic compound in the antireflective film.

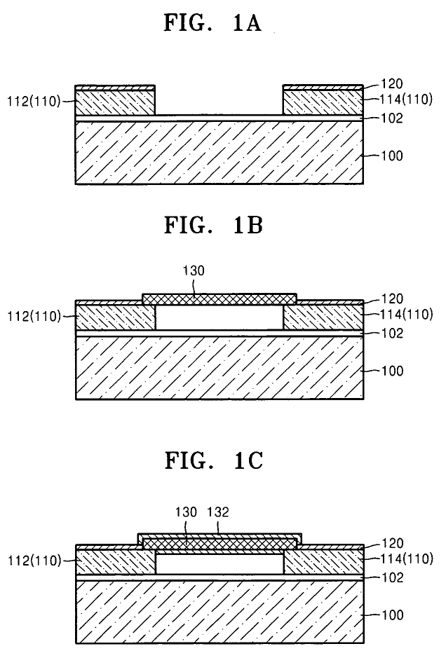

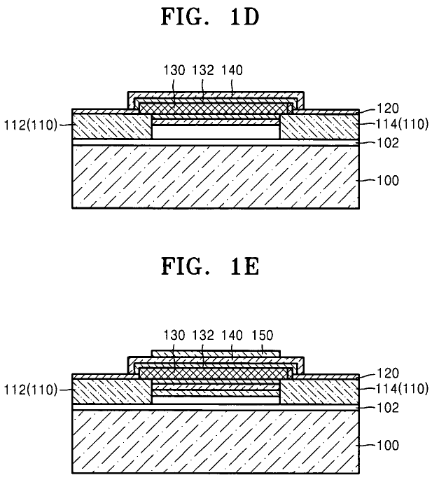

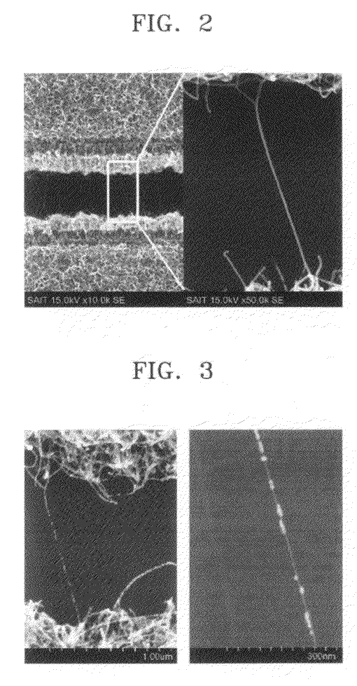

### BACKGROUND OF THE INVENTION

1. Field of the Invention

The present invention relates to a method for forming a photoresist pattern by making use of a top antireflective film as well as to a photoresist laminate for use in such a method. The present invention is particularly suitable for forming ultrafine photoresist patterns with a pattern width of 0.25 μm or less.

2. Description of Related Art

As semiconductor devices are becoming ever more highly integrated, new techniques have been developed that are adapted to fine processing required in the production of semiconductor devices. The same is also true for the photolithography process, a key process in the production of semiconductor devices, in which demand for the fine processing has reached to the point where a pattern width of 0.25 μm or less is required. To that end, various approaches have been attempted for forming ultrafine photoresist patterns by taking advantage of photoresist materials that function with short-wavelength radiations such as KrF, ArF, and F₂ excimer lasers.

It has now become an important technical challenge to adapt the existing processes employing a photoresist for KrF excimer laser to form even finer high-precision photoresist patterns.

With regard to photolithographic techniques for forming photoresist patterns, a method is known in which an antireflective film (top antireflective film) is deposited on top of the photoresist film in order to prevent multiple interference of light from occurring within the photoresist film and to thereby prevent variation in the pattern width of the photoresist pattern, which would otherwise result from the variation in the thickness of the photoresist film. The photoresist is then exposed and developed to form a desired photoresist pattern.

In view of such conditions of the current state of the art, different proposals have been made concerning the materials of the antireflective film and the photoresist film. In one such proposal, a material for the antireflective film comprises a composition that contains as essential components a water-soluble component for forming the film and a fluorine-based surfactant (Japanese Patent Laid-Open Publications Nos. 5-188598 and 8-15859, etc.). For a material for the photoresist film, chemically amplified photoresists, which comprise a base resin and an acid-generating agent that generates acid upon exposure to radiation, have become an increasingly popular. Of such chemically amplified photoresists, a composition containing, as the base resin, a resin that comprises at least polyhydroxystyrene units and (meth)acrylate units and an onium salt-based agent as the acid-generating agent is known as a suitable photoresist material for use with KrF excimer laser. The (meth)acrylate units are protected by protective groups such as tert-butyl. A preferred onium salt-based agent contains sulfonate ions (anion) such as nonafluorobutane sulfonate ions and trifluoromethane sulfonate ions.

As described above, while considerable effort has been made to find suitable materials independently for the antireflective film and the photoresist film for the purpose of forming finer patterns, little attention has been directed to finding suitable combinations of the antireflective film and the photoresist film. Seeking individual solutions individually for the photoresist film and the top antireflective film is not practical considering the recent demand for fine pattering, in particular for forming patterns with a pattern width of 0.25 μm or less. It is thus necessary to examine potential synergetic effects of combinations of the two. Although much effort has been devoted to improving resins in photoresist materials, such effort has brought about other problems, including decreased depth of focus.

### SUMMARY OF THE INVENTION

With the aim of solving the aforementioned problems, the present invention provides a novel method for forming a photoresist pattern. The method involves the steps of depositing a photoresist film on a substrate, the photoresist film containing an acid-generating agent capable of generating an acid upon exposure to light; overlaying an antireflective film over the photoresist film, the antireflective film containing a fluorine-based acidic compound; selectively exposing the photoresist; and developing the photoresist. The method of the present invention is characterized in that the acid-generating agent and the fluorine-based acidic compound are selected so that the acid that the acid-generating agent generates in the photoresist film upon exposure to light has a higher acidity than the fluorine-based acidic compound in the antireflective film.

The present invention also provides a novel photoresist laminate, which consists of a photoresist film containing an acid-generating agent capable of generating an acid upon exposure to light and an antireflective film containing an fluoride-based acidic compound and overlaid on top of the photoresist film. The photoresist laminate of the present invention is characterized in that the acid that the acid-generating agent generates in the photoresist film upon exposure to light has a higher acidity than the fluorine-based acidic compound in the antireflective film.

### DETAILED DESCRIPTION OF THE INVENTION

In the present invention, a chemically amplified photoresist composition containing an acid-generating agent capable of generating acid upon exposure to light is used for forming a photoresist film. A specific type of the photoresist composition that is particularly suitable for the purpose of forming ultra fine patterns with a pattern width of 0.25 μn or less is a chemically amplified positive photoresist composition containing, for example, (B) 1-20 parts by mass of an onium salt serving as an acid-generating agent and containing fluoroalkylsulfonate ions (anion) having 1-5 carbon atoms with respect to (A) 100 parts by mass of a resin component including at least polyhydroxystyrene units and (meth)acrylate units protected by a protective group for preventing the component (A) from dissolving that can be eliminated by an acid (e.g., tert-butyl).

Preferably, the component (A) is a copolymer resin component composed of (a-1) 50-85 mol % of hydroxyl-containing styrene units; (a-2) 15-35 mol % of styrene units; and (a-3) 2-20 mol % of (meta)acrylate units having a protective group for preventing the component (A) from dissolving that can be eliminated by an acid. In particular, the unit (a-1) needs to be a styrene unit having at least one hydroxyl group in terms of the solubility in an alkaline solution. Specific examples of the unit (a-1) includes hydroxystyrene units and α-methylhydroxystyrene units.

The unit (a-3) has a carboxyl group protected by a protective group for preventing the component (A) from dissolving in an alkaline solution. The protective group is eliminated by the action of an acid, which the below-described acid-generating agent, or the component (B), generates when exposed to light. As a result, free carboxyl groups are formed and the photoresist becomes soluble in an alkaline solution, so that a photoresist pattern can be formed in a development process using an alkaline solution.

The protective group of the unit (a-3) that can be eliminated by an acid may be any known protective group: Particularly preferred are tertiary alkyl groups, such as tert-butyl and tert-pentyl, and chain or cyclic alkoxyalkyl groups, such as 1-ethoxyethyl, 1-methoxypropyl, tetrahydrofuranyl and tetrahydropyranyl. These protective groups may be used independently or in combinations of two or more.

Specific examples of the unit (a-3) having the chain or cyclic alkoxyalkyl group as the protective group are shown by the following general formulae (I)-(IV), wherein R represents hydrogen or methyl.

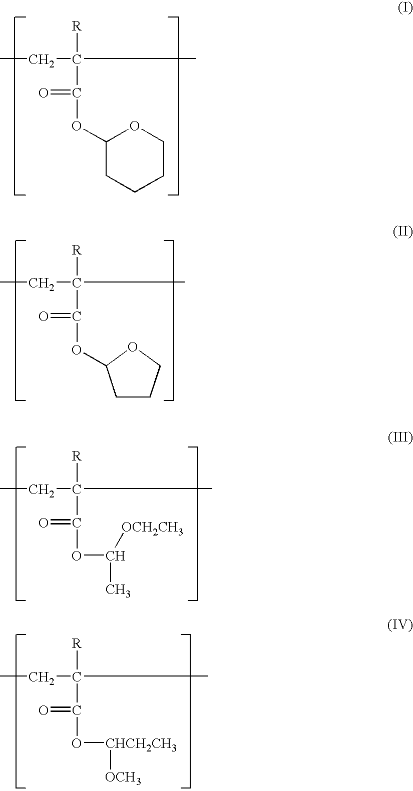

Particularly preferred examples of the unit-(a-3) include tert-butyl (meth)acrylate unit, 1-ethoxyethyl (meth)acrylate unit, and tetrahydropyranyl (meth)acrylate unit, each of which can readily dissociate in the presence of an acid and is thus suited for the formation of accurate photoresist patterns.

The use of the copolymer containing the unit (a-1), the unit (a-2), and the unit (a-3) in the above-specified proportion to serve as the component (A) is preferred since the copolymer is significantly more effective in preventing the photoresist from dissolving in an alkaline solution than are the conventional resins, which have anti-dissolving groups partially introduced in polyhydroxystyrene, so that the loss of the film in the unexposed regions is significantly reduced and thus, better featured photoresist patterns can be obtained.

While the above-described copolymers may be used either individually or in combinations of two or more copolymers in the photoresist for use in the present invention, it is particularly preferred to use a copolymer mixture containing a first copolymer composed of 62-68 mol % of the unit (a-1), 15-25 mol % of the unit (a-2) and 12-18 mol % of the unit (a-3), and a second copolymer composed of 62-68 mol % of the unit (a-1), 25-35 mol % of the unit (a-2), and 2-8 mol % of the unit (a-3), at a mass ratio of the first copolymer to the second copolymer of 9:1 to 5:5, preferably at a mass ratio of 8:2 to 6:4. Such a copolymer composition is advantageous since it can provide a better sensitivity and resolution, as well as better featured photoresist patterns.

The mass average molecular weight of the copolymer to serve as the component (A) is preferably in the range of 3,000-30,000 as measured by the gel permeation chromatography (GPC) using polystyrene as a standard. The mass average molecular weight smaller than the lower limit of this range can result in a reduced coating performance, whereas the mass average molecular weight exceeding the upper limit of the range can lead to a decreased solubility in the alkaline solution.

The acid-generating agent to serve as the component (B), a compound capable of generating acid upon exposure to radiation, is an onium salt containing fluoroalkylsulfonate ions (anion) having 1 to 5 carbon atoms. While a cation to form of the onium salt may be any of conventionally known cations, preferred examples are phenyl iodonium and sulfonium, which may have, as a substituent, a lower alkyl group such as methyl, ethyl, propyl, n-butyl and tert-butyl or a lower alkoxy group such as methoxy and ethoxy.

An anion of the onium salt, on the other hand, is fluoroalkylsulfonate ion that has an alkyl group having 1-5 carbon atoms with some or all of its hydrogen atoms substituted with fluorine atoms. Since the acidity of the fluoroalkylsulfonic acid tends to decrease as its carbon chain becomes longer and its fluorination rate (i.e., the proportion of fluorine-substituted hydrogen atoms in the alkyl group) becomes smaller, perfluoroalkylsulfonate ions having an alkyl with 1 to 5 carbon atoms with all of its hydrogen atoms substituted with fluorine atoms are preferred.

Examples of such an onium salt include an iodonium salt represented by the following general formula (V):

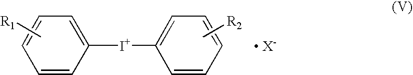

wherein R₁ and R₂ each independently represent a hydrogen, an alkyl or alkoxy group having 1-4 carbon atoms, and X⁻ represents a fluoroalkylsulfonate ion having 1-5 carbon atoms, and a sulfonium salt represented by the following general formula (VI):

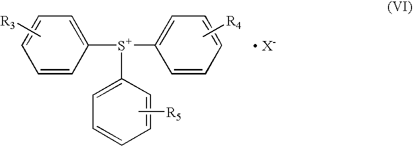

wherein R₃, R₄ and R₅ each independently represent a hydrogen, an alkyl or alkoxy group having 1-4 carbon atoms, and X⁻ is the same as defined above.

Preferred examples of the onium salt include diphenyliodonium trifluoromethanesulfonate, diphenyliodonium nonafluorobutanesulfonate, bis(4-tert-butylphenyl)iodonium nonafluorobutanesulfonate, triphenylsulfonium nonafluorobutanesulfonate, and tri(4-methylphenyl)sulfonium nonafluorobutanesulfonate. Of these, particularly preferred are diphenyliodonium trifluoromethanesulfonate, diphenyliodonium nonafluorobutanesulfonate, and bis(4-tert-butylphenyl)iodonium nonafluorobutanesulfonate.

Compounds as the component (B) can be used either singly or in admixture. The amount of the component (B) is selected to be in the range of 1-20 parts by mass with respect to 100 parts by mass of the component (A). The amount of the component (B) less than 1 part by mass makes it difficult to obtain high-quality images, whereas the amount greater than 20 parts by mass tends to result in non-uniform solutions and thus a decreased storage stability.

If necessary, the chemically amplified positive photoresist suitable for use in the present invention may contain, in addition to the above-described components (A) and (B), a secondary amine or a tertiary amine as a component (C) for the purposes of preventing unnecessary dispersion of the acid generated by exposure to radiation and accurately transferring a pattern on a photomask onto the photoresist.

Examples of the secondary amine include aliphatic secondary amines, such as diethylamine, dipropylamine, dibutylamine, and dipentylamine.

Examples of the tertiary amine include aliphatic tertiary amines, such as trimethylamine, triethylamine, tripropylamine, tributylamine, tripentylamine, N,N-dimethylpropylamine, N-ethyl-N-methylbutylamine; tertiary alkanolamines, such as N,N-dimethylmonoethanolamine, N,N-diethylmonoethanolamine, and triethanolamine; and aromatic tertiary amines, such as N,N-dimethylaniline, N,N-diethylaniline, N-ethyl-N-methylaniline, N,N-dimethyltoluidine, N-methyldiphenylamine, N-ethyldiphenylamine, and triphenylamine.

Compounds as the component (C) can be used either singly or in admixture. Of these, tertiary alkanolamines are preferred, with lower aliphatic tertiary alkanolamines having 2-4 carbon atoms, such as triethanolamine, being particularly preferred.

The amount of the component (C) is preferably in the range of 0.001-10 parts by mass, and more preferably in the range of 0.01-1.0 parts by mass, with respect to 100 parts by mass of the component (A). In this manner, the unnecessary dispersion of the acid generated by exposure to radiation is prevented, so that the pattern on a photomask can be accurately transferred onto the photoresist.

If desired, the photoresist may further contain, along with the component (C), an organic carboxylic acid as a component (D) for the purposes of preventing the sensitivity loss due to the component (C) and further improving the resolution.

Examples of such an organic carboxylic acid include saturated aliphatic carboxylic acids, alicyclic carboxylic acids, and aromatic carboxylic acids. Examples of the saturated aliphatic carboxylic acid include monocarboxylic or polycarboxylic acids, such as butyric acid, isobutyric acid, malonic acid, succinic acid, glutaric acid, and adipic acid. Examples of the alicyclic carboxylic acid include 1,1-cyclohexanedicarboxylic acid, 1,2-cyclohexanedicarboxylic acid, 1,3-cyclohexanedicarboxylic acid, 1,4-cyclohexanedicarboxylic acid, and 1,1-cyclohexanediacetic acid. Example of the aromatic carboxylic acid include aromatic monocarboxylic acids or polycarboxylic acids having substituents such as hydroxyl and nitro groups, such as o-, m-, or p-hydroxybenzoic acid, 2-hydroxy-3-nitrobenzoic acid, phthalic acid, terephthalic acid, and isophthalic acid. Compounds as the component (D) can be used either singly or in admixture.

Of the members of the component (D), aromatic carboxylic acids are preferred because of their ideal acidities. In particular, o-hydroxybenzoic acid is suitably used since it is highly soluble in photoresist solvents and is suited for forming high-quality photoresist patterns on various substrates.

The amount of the component (D) is typically in the range of 0.001-10 parts by mass, and preferably in the range of 0.01-1.0 parts by mass, with respect to 100 parts by mass of the component (A). In this manner, the loss of the sensitivity due to the component (C) is prevented and the resolution is further improved.

Preferably, the positive photoresist is used in the form of a solution prepared by dissolving the above-described components in a proper solvent. Examples of such a solvent include ketones, such as acetone, methyl ethyl ketone, cyclohexanone, methyl isoamyl ketone and 2-heptanone; polyols and derivatives thereof, such as ethylene glycol, ethylene glycol monoacetate, diethylene glycol, diethylene glycol monoacetate, propylene glycol, propylene glycol monoacetate, dipropylene glycol and dipropylene glycol monoacetate, and monomethylether, monoethylether, monopropylether, monobutylether and monophenylether thereof; cyclic ethers, such as dioxane; and esters, such as methyl lactate, ethyl lactate, methyl acetate, ethyl acetate, butyl acetate, methyl pyruvate, ethyl pyruvate, methyl methoxypropionate, and ethyl ethoxypropionate. These solvents may be used individually or in combinations of two or more solvents.

If necessary, the photoresist may further contain additives that can be mixed therewith. For example, an additional resin, plasticizer, stabilizer, color, and surfactant that are commonly in use for improving the performance of the photoresist film may be added.

An antireflective film for use in the present invention contains a fluorine-based acidic compound.

Preferred examples of the fluorine-based acidic compound include compounds represented by the following general formula (VII):

RfCOOH (VII)

wherein Rf represents a saturated or unsaturated fluorinated hydrocarbon group having 5-10 carbon atoms that has all or some of its hydrogen atoms substituted with fluorine atoms, and compounds represented by the following general formula (VIII):

RfSO₃H (VIII)

wherein Rf is the same as defined above.

Examples of the compound of the general formula (VII) include perfluoroheptanoic acid and perfluorooctanoic acid, while examples of the compound of the general formula (VIII) include perfluorooctylsulfonic acid and perfluorodecylsulfonic acid. Specifically, perfluorooctanoic acid and perfluorooctylsulfonic acid are marketed under the product names of EF-201 and EF-101, respectively (Tohchem Products Co.), and each of these products can be suitably used. Of the fluorine-based acidic compounds, perfluorooctylsulfonic acid and perfluorooctanoic acid are particularly preferred because of their ability to prevent interference, high solubility in water, and readiness in adjusting pH.

The fluorine-based acidic compound is typically present in the photoresist composition in the form of a salt that the compound forms with a base. A preferred base may be one or two or more selected from the group consisting of quaternary ammonium hydroxides and alkanolamines, though any base may be used. Examples of the quaternary ammonium hydroxide include tetramethylammonium hydroxide (TMAH) and (2-hydroxylethyl)trimethylammonium hydroxide (also known as choline). Examples of the alkanolamine include monoethanolamine, N-methylethanolamine, N-ethylethanolamine, diethanolamine, and triethanolamine.

In general, the antireflective film further contains a water-soluble, film-forming component.

Examples of the water-soluble, film-forming component include cellulose-based polymers, such as hydroxypropyl methylcellulose phthalate, hydroxypropyl methylcellulose acetate phthalate, hydroxypropyl methylcellulose acetate succinate, hydroxypropyl methylcellulose hexahydrophthalate, hydroxypropyl methylcellulose, hydroxypropylcellulose, hydroxyethylcellulose, cellulose acetate hexahydrophthalate, carboxymethylcellulose, ethylcellulose and methylcellulose; acrylic acid-based polymers consisting of monomer units such as N,N-dimethylacrylamide, N,N-dimethylaminopropylmethacrylamide, N,N-dimethylaminopropylacrylamide, N-methylacrylamide, diacetoneacrylamide, N,N-dimethylaminoethylmethacrylate, N,N-diethylaminoethylmethacrylate, N,N-dimethylaminoethylacrylate, acryloyl morpholine and acrylic acid; and vinyl-based polymers such as polyvinyl alcohol and polyvinylpyrrolidone. Of these, acrylic acid-based polymers and polyvinylpyrrolidone, each being a water-soluble polymer having no hydroxyl groups within the molecule, are preferred, with polyvinylpyrrolidone being particularly preferred. These compounds may be used individually or in combinations of two or more to serve as the water-soluble, film-forming component.

The composition for forming the antireflective film is typically used in the form of an aqueous solution and preferably contains the water-soluble, film-forming component in an amount of 0.5-10.0% by mass. It is preferred that the at least one salt selected from the group consisting of the salts that the compound of the general formula (VII) forms with the base and the salts that the compound of the general formula (VIII) forms with the base be contained in an amount of 1.0-15.0% by mass.

The antireflective film may optionally contain additional components such as anionic surfactants and N-alkyl-2-pyrrolidone.

Preferably, the anionic surfactant is selected from diphenylether derivatives represented by the following general formula (IX):

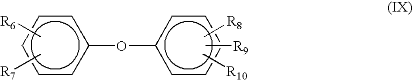

wherein at least one of R₆ and R₇ is an alkyl or alkoxy group having 5-18 carbon atoms and the other is a hydrogen or an alkyl or alkoxy group having 5-18 carbon atoms; at least one of R₈, R₉, and R₁₀, is an ammonium sulfonate group or a substituted ammonium sulfonate group and the others are each independently a hydrogen, or an ammonium sulfonate group or a substituted ammonium sulfonate group. As just mentioned, at least one of R₈, R₉ and R₁₀ in the general formula (IX) is an ammonium sulfonate group or a substituted ammonium sulfonate group. The substituted ammonium sulfonate group may be any of mono-, di-, tri-, or tetra-substituted ammonium groups, with the substituent being selected for example from —CH₃, —C₂H₅, —CH₂OH, and —C₂H₄OH. As for the multi-substituted ammoniums, the substituents may or may not be identical to one another.

It is preferred that the following conditions are met for the general formula (IX): R₆ is an alkyl or alkoxy group having 5-18 carbon atoms; R₇ is a hydrogen or an alkyl or alkoxy group having 5-18 carbon atoms; R₈ is an N-substituted or unsubstituted ammonium sulfonate group represented by the following general formula: —SO₃NZ₄ (wherein Zs are each independently a hydrogen, an alkyl group having 1 or 2 carbon atoms, or a hydroxyalkyl group having 1 or 2 carbon atoms); and R₉ and R₁₀ are each independently a hydrogen or an N-substituted or unsubstituted ammonium sulfonate group represented by the following general formula: —SO₃NZ₄ (wherein Zs are the same as defined above).

Specific examples of the anionic surfactant represented by the general formula (IX) include, but are not limited to, ammonium alkyldiphenylether sulfonate, tetramethylammonium alkyldiphenylether sulfonate, trimethylethanolammonium alkyldiphenylether sulfonate, triethylammonium alkyldiphenylether sulfonate, ammonium alkyldiphenylether disulfonate, diethanolammonium alkyldiphenylether disulfonate, and tetramethylammonium alkyldiphenylether disulfonate. The alkyl groups in the above-described compound have 5-18 carbon atoms and may be substituted with alkoxy groups having 5-18 carbon atoms. Shown below by the general formulae (X)-(XXII) are specific examples of the compound of the general formula (IX).

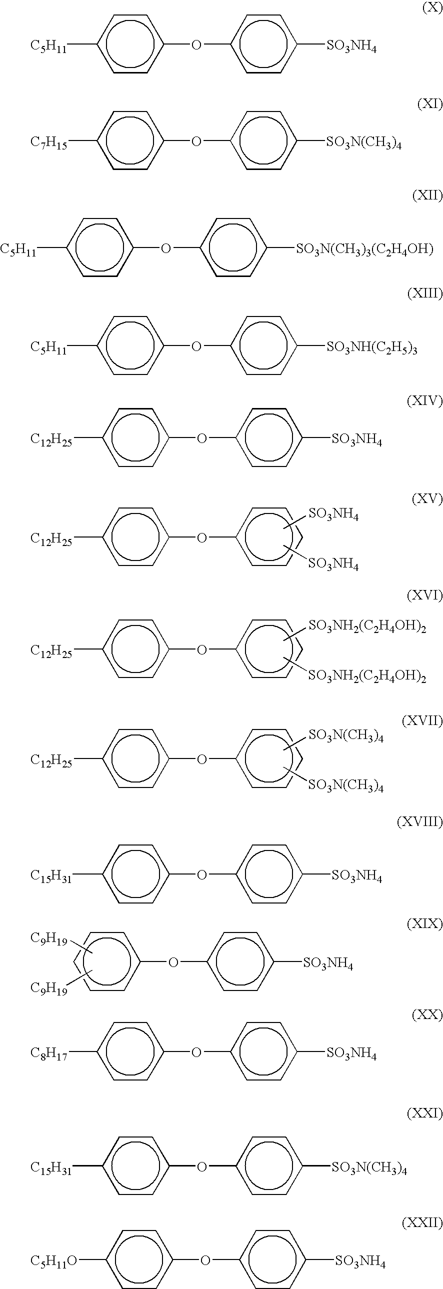

Of these anionic surfactants of the general formula (IX), preferred are ammonium alkyldiphenylether disulfonates in which R₆ is an alkyl group having 5-18 carbon atoms, R₇ is a hydrogen, R₈ and R₉, are each —SO₃NH₄, and R₁₀ is a hydrogen, with the one represented by the general formula (XV) being particularly preferred. These anionic surfactants may be used individually or in combinations of two or more surfactants. Addition of the anionic surfactant effectively prevents non-uniformity of the antiinterference coating thereby to ensuring uniform coating, and photoresist patterns faithfully reflecting mask-patterns can be effectively obtained.

The anionic surfactant represented by the general formula (XV) is preferably added in an amount of 500-10,000 ppm, in particular 1,000-5,000 ppm, with respect to the solution for forming antireflective film in which the water-soluble, film-forming component has been dissolved along with the fluorine-based surfactant.

Preferably, N-alkyl-2-pyrrolidones represented by the following general formula (XXIII) are used:

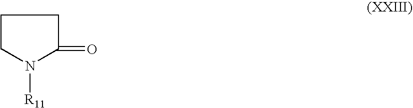

wherein R₁₁ represents an alkyl group having 6-20 carbon atoms.

Specific examples of the compound of the general formula (XXIII) include N-hexyl-2-pyrrolidone, N-heptyl-2-pyrrolidone, N-octyl-2-pyrrolidone, N-nonyl-2-pyrrolidone, N-decyl-2-pyrrolidone, N-undecyl-2-pyrrolidone, N-dodecyl-2-pyrrolidone, N-tridecyl-2-pyrrolidone, N-tetradecyl-2-pyrrolidone, N-pentadecyl-2-pyrrolidone, N-hexadecyl-2-pyrrolidone, N-heptadecyl-2-pyrrolidone, and N-octadecyl-2-pyrrolidone. Of these, N-octyl-2-pyrrolidone and N-dodecyl-2-pyrrolidone are marketed by ISP Japan Co., Ltd., under the product names of SURFADONE LP100 and SURFADONE LP300, respectively, and are preferred for their availability. Addition of these compounds enhances coatability of the composition, so that uniform coating can be obtained to the edge of the substrate while requiring a minimum amount of the coating.

The compound is preferably added in an amount of 100-10,000 ppm, particularly 150-5,000 ppm, with respect to the coating solution in which the water-soluble, film-forming component has been dissolved along with the fluorine-based surfactant.

As described above, while the coating solution for forming antireflective film for use in the present invention is typically used in the form of an aqueous solution, an alcohol-based organic solvent, such as isopropyl alcohol, may further be added, when necessary, to the solution since such a solvent can enhance the solubility of the fluorine-based surfactant and thus improve the uniformity of the coating. The amount of the alcohol-based organic solvent is preferably in the range of 20% by mass or less with respect to the total amount of the coating solution.

The patterning method of the present invention is particularly advantageous in that it can improve insufficient formation of the top portion of the photoresist pattern, which is caused by the presence of excessive acid (acidic compound), such as trifluoromethanesulfonic acid and nonafluorobutanesulfonic acid, that is generated within the photoresist during exposure. The method works by taking advantage of the presence of the basic compound that can form a salt with the fluorine-based acidic compound, such as perfluorooctylsulfonic acid and perfluorooctanoic acid, existing within the top antireflective film. The underlying principle is believed to be that the acid generated upon exposure to light within the photoresist film in the vicinity of the interface between the top antireflective film and the photoresist film exchanges a salt with the fluorine-based acidic compound pre-sent in the top antireflective film. Thus, it is important that the acid generated within the photoresist film upon exposure to light has a higher acidity than the fluorine-based acidic compound present in the top antireflective film.

For this reason, it is preferred to use perfluorooctylsulfonic acid and/or perfluorooctanoic acid to serve as the fluorine-based acidic compound for use in the top antireflective film, in combination with diphenyliodonium trifluoromethanesulfonate and/or diphenyliodonium nonafluorobutanesulfonate as the acid-generating agent for use in the photoresist composition that determines the type of the acid (acidic compound) generated within the photoresist film upon exposure to light.

One example of the method of the present invention using a photoresist film and an antireflective film, each constructed according to the foregoing description, is as follows:

First, a photoresist layer is deposited on a substrate, such as a silicon wafer, and a coating solution for antireflective film is applied over the photoresist layer by the spinner method. Then, the substrate is baked to form an antireflective film over the photoresist layer, thus completing a double-layered photoresist laminate. It should be noted that baking is not necessary if a uniform, high-quality film can be formed simply by applying the coating solution.

Subsequently, using an exposure apparatus, an activation light, such as far ultraviolet radiation (including excimer laser), is selectively irradiated onto the photoresist layer through the antireflective film.

The antireflective film has an optimum thickness for effectively reducing interference of activation light. This thickness is defined as an odd multiple of λ/4n (where λ is the wavelength of the activation light, and n is the refractive index of the antireflective film). For example, for the antireflective film with a refractive index of 1.35, the optimum thickness for far ultraviolet ray (excimer laser) will be odd multiples of 46 nm. In practice, it is desirable that the film thickness fall within a ±5 nm range of the optimum thickness.

When deposited on a negative or positive chemically amplified photoresist layer, the antireflective film, in addition to exhibiting the antireflective effects, can help improve shapes of photoresist patterns and is thus preferred. In general, surfaces of the layer of the chemically amplified photoresist composition are subjected to a vapor of organic alkaline compounds, such as N-methyl-2-pyrrolidone, ammonia, pyridine, and triethylamine, that exist in the atmosphere of production facilities of semiconductor devices. As a result, the surface of the photoresist layer becomes deprived of acid, which often leads to formation of photoresist patterns with rounded top portions when a negative photoresist composition is used and to formation of interconnected ‘eaves-like’ photoresist patterns when a positive photoresist is used. The ability of the antireflective film to help improve shapes of photoresist patterns can thus be rephrased as an ability to eliminate occurrences of such phenomena and to thereby make it possible to form photoresist patterns reflecting faithfully the pattern-of-the-mask and their cross-sectional shapes are rectangular. Accordingly, the antireflective film can also serve as a suitable protective material for the chemically amplified photoresist layer.

After exposure and a subsequent post-bake, the antireflective film is removed prior to development. This removal process can be carried out by applying a solvent capable of dissolving the antireflective film while the silicon wafer is being spun on a spinner. In this manner, only the antireflective film is completely removed. The solvent for removing the antireflective film may be a fluorine-based organic solvent or an aqueous solution of a surfactant. One advantage of the method of the present invention is that the antireflective film, once removed by the fluorine-based organic solvent, can be collected, distilled for purification, and concentration-adjusted for recycling and can thus help reduce manufacturing costs.

After removal of the antireflective film, a development process is carried out by an ordinary method. Through the series of processes, photoresist patterns with good shapes are formed on the surface of the silicon wafer.

The method of the present invention can be used to form photoresist patterns with a pattern width of 0.25 μm or less and patterns those duty ratio is 1:1 or less are advantageously obtained, and can effectively prevent top portions of respective photoresist patterns from adhering to one another. The term “duty ratio” as used herein refers to a ratio between the width of the photoresist pattern that serves as a mask during etching and the diameter or width of an etch-formed hole pattern or line pattern. A “pattern having a duty ratio of 1:1 or less” means a pattern of which the ratio of the diameter or width of an etch-formed hole pattern or line pattern to the width of the photoresist pattern as a mask is 1 or more.

### EXAMPLES

The present invention is now described in a further detail with reference to examples, which are only illustrative and are not intended to limit the scope of the invention in any way.

### Example 1

Using a spinner, a positive photoresist containing a polyhydroxystyrene-based resin and diphenyliodonium trifluoromethanesulfonate was applied to a silicon wafer. The wafer was then heated at 140° C. on a hot plate for 90 seconds to form a 560 nm thick photoresist film.

As a coating for forming top antireflective film, TSP-10A (manufactured by Tokyo Ohka Kogyo Co., Ltd.), which contained perfluorooctylsulfonic acid (EF-101) and polyvinylpyrrolidone, was applied over the photoresist film. The wafer was then heated at 60° C. for 60 seconds to form a 44 nm thick antireflective film.

Using an excimer laser scanner (S203B manufactured by Nikon Corp.), the silicon wafer was exposed through a mask pattern. The wafer was then baked on a hot plate at 140° C. for 90 seconds, developed using the puddle development technique in an aqueous solution of 2.38% by mass of tetramethylammonium hydroxide (TMAH) at 23° C. for 60 seconds, and then washed with pure water.

The resulting hole pattern, which was 0.15 μm in diameter and had a duty ratio of 1:1, was observed with SEM (scanning electron microscope). It was observed that the hole pattern had a finely featured profile, with its cross-sectional shape being rectangular.

### Example 2

A similar hole pattern with a diameter of 0.15 μm and a duty ratio of 1:1 was formed in the same manner as in Example 1, except that TSP-8A (Tokyo Ohka Kogyo Co., Ltd.), which contained perfluorooctanoic acid (EF-201) in place of perfluorooctylsulfonic acid, was used as the material for antireflective film. The resulting hole pattern was observed as in Example 1. It was observed that the hole pattern had a finely featured profile, with its cross-sectional shape being rectangular.

### Example 3

A similar hole pattern with a diameter of 0.15 μm and a duty ratio of 1:1 was formed in the same manner as in Example 1, except that a different positive photoresist, which contained diphenyliodonium nonafluorobutanesulfonate in place of diphenyliodonium trifluoromethanesulfonate, was used. The resulting hole pattern was observed as in Example 1. It was observed that the hole pattern had a finely featured profile, with its cross-sectional shape being rectangular.

### Comparative Example 1

A similar hole pattern with a diameter of 0.15 μm and a duty ratio of 1:1 was formed in the same manner as in Example 1, except that a different positive photoresist, which contained an acetal-based resin and a diazomethanesulfonic acid-based acid-generating agent, was used in place of the positive photoresist of Example 1. Furthermore, an additional hole pattern was formed in the same manner except that the top reflective film was not provided. It was observed that each of the holes had its top portion rounded and was therefore not suited for practical use.

As set forth, the present invention makes it possible to select an optimum combination of antireflective film and photoresist film, so that, when it is desired to form fine patterns, in particular patterns with a pattern width of 0.25 μm or less, finely featured profiles of the photoresist patterns are ensured without having to introduce a special equipment.

What is claimed is:

1. A method for forming a photoresist pattern, comprising:
depositing a photoresist film on a substrate, the photoresist film containing an acid-generating agent capable of generating an acid upon exposure to light;
overlaying an antireflective film over the photoresist film, the antireflective film containing a fluorine-based acidic compound, wherein the acid-generating agent and the fluorine-based acidic compound are selected so that the acid that the acid-generating agent generates in the photoresist film upon exposure to light has a higher acidity than the fluorine-based acidic compound in the antireflective film;
selectively exposing the photoresist to light; and
developing the photoresist.

2. The method for forming a photoresist pattern according to claim 1, wherein the acid that the acid-generating agent generates in the photoresist film upon exposure to light is a perfluoroalkylsulfonic acid with an alkyl group that has 1-5 carbon atoms and has all of its hydrogen atoms substituted with fluorine atoms, and the fluorine-based acidic compound in the antireflective film is perfluorooctylsulfonic acid and/or perfluorooctanoic acid.

3. The method for forming a photoresist pattern according to claim 1, wherein the acid that the acid-generating agent generates in the photoresist film upon exposure to light is trifluoromethanesulfonic acid and/or nonafluorobutanesulfonic acid, and the fluorine-based acidic compound in the antireflective film is perfluorooctylsulfonic acid and/or perfluorooctanoic acid.

4. A photoresist laminate comprising:
a photoresist film containing an acid-generating agent capable of generating an acid upon exposure to light; and
an antireflective film containing an fluoride-based acidic compound and overlaid on top of the photoresist film, wherein
the acid that the acid-generating agent generates in the photoresist film upon exposure to light has a higher acidity than the fluorine-based acidic compound in the antireflective film.

5. The photoresist laminate according to claim 4, wherein the acid that the acid-generating agent generates in the photoresist film upon exposure to light is a perfluoroalkylsulfonic acid with an alkyl group that has 1-5 carbon atoms and has all of its hydrogen atoms substituted with fluorine atoms, and the fluorine-based acidic compound in the antireflective film is perfluorooctylsulfonic acid and/or perfluorooctanoic acid.

6. The photoresist laminate according to claim 4, wherein the acid that the acid-generating agent generates in the photoresist film upon exposure to light is trifluoromethanesulfonic acid and/or nonafluorobutanesulfonic acid, and the fluorine-based acidic compound in the antireflective film is perfluorooctylsulfonic acid and/or perfluorooctanoic acid.
